(19) United States
(12) Patent Application Publication
(10) Pub. No.: US 2022/0012576 A1
(43) Pub. Date: Jan. 13, 2022

(54) CHARGE TRAP BASED NEUROMORPHIC SYNAPTIC TRANSISTOR WITH IMPROVED LINEARITY AND SYMMETRICITY BY SCHOTTKY JUNCTIONS, AND A NEUROMORPHIC SYSTEM USING IT

(71) Applicant: Korea Advanced Institute Of Science And Technology, Daejeon (KR)

(72) Inventors: Yang-Kyu CHOI, Daejeon (KR); Joon-Kyu HAN, Daejeonn (KR); Geon-Beom LEE, Daejeon (KR); Jinki KIM, Daejeon (KR)

(21) Appl. No.: 17/371,364

(22) Filed: Jul. 9, 2021

(30) Foreign Application Priority Data
Jul. 9, 2020 (KR) 10-2020-0084648
Nov. 24, 2020 (KR) 10-2020-0158527

(51) Int. Cl. G06N 3/063; H01L 29/872

(52) U.S. Cl. CPC G06N 3/063; H01L 29/1608; H01L 29/872

(57) ABSTRACT

A neuromorphic synaptic device based on a charge trap and having linearity and symmetricity improved by using a schottky junction and a neuromorphic system using the same are provided. The neuromorphic synaptic device includes a body layer formed on a semiconductor substrate, a source and a drain formed at a left side and a right side, or an upper side and a lower side of the body layer, a contact metal to form a schottky junction by making contact with the source and the drain, a gate insulating layer formed on the body layer, and including an oxide layer and a charge storage layer, and a gate formed on the gate insulating layer.

### CROSS-REFERENCE TO RELATED APPLICATIONS

A claim for priority under 35 U.S.C. § 119 is made to Korean Patent Application No. 10-2020-0084648 filed on Jul. 9 2020, in the Korean Intellectual Property Office, the entire contents of which are hereby incorporated by reference.

### BACKGROUND

Embodiments of the inventive concept described herein relate to a neuromorphic synaptic device based on a charge trap and having improved linearity and symmetricity, and a neuromorphic system using the same, and more particularly, relate to a technology of improving linearity and symmetricity which are the most important indexes of the neuromorphic synaptic device, by intentionally generating a region, through which a schottky tunneling current flows, using the schottky junction.

With the limitation in scaling a transistor, a neuromorphic computing system has been spotlighted as a new concept to overcome the limitation of an existing computer system employing a von Neumann scheme.

The neuromorphic computing is a scheme to implement an artificial intelligent (AI) operation by emulating a human brain in hardware. In more detail, the neuromorphic computing emulates the brain structure of a human being, based on the fact that the brain of the human being consumes only the energy of 20 W, even in the significantly complex structure. Accordingly, the neuromorphic computing more excellently performs the AI operation in an ultra-low power, as compared to the existing von Neumanne scheme.

A neuromorphic system employing the neuromorphic computing scheme includes numerous synapses, similarly to the brain of the human being. The synapse memorizes a synaptic weight, based on the relationship between spikes produced from neurons, and adjusts the synaptic weight through a potentiation or depression procedure of the synaptic weight depending on occasions. In this case, the synaptic weight is expressed as the conductance of the synapse. Researches and studies have been conducted on synapse devices based on a resistive random access memory or a memristor, but the synaptic devices have big problems in reliability and process compatibility with a CMOS technology. Accordingly, recently, a silicon-based charge trap flash memory device has been actively studied as alternatives. The synaptic device expresses the synaptic weight based on an amount of charges stored in a storage charge layer present in a gate of the transistor.

Meanwhile, the linearity of a potentiation/depression curve representing the potentiation/depression of the conductance of the synaptic device is a factor to directly exert an influence on a learning capability of the synaptic device. The charge trap flash memory device injects or removes charges through an owler-Nordheim (FN) tunneling. The conductance changed depending on charges shows the log function depending on the number of times of an input signals. Accordingly, the conductance shows the form of a non-linear and asymmetric curve, thereby reducing the learning efficiency.

Although researches and studies have been conducted on adjusting an input signal applied to a synapse to improve the linearity and the symmetricity, an additional circuit is required. Accordingly, the integration and the operating speed may be degraded. Therefore, there are required a method and an invention capable of basically improve the linearity and the symmetricity even for a specific input signal.

### SUMMARY

Embodiments of the inventive concept provide a neuromorphic synaptic device based on a charge trap and having linearity and symmetricity improved using a schottky junction, capable of improving the linearity and the symmetricity of a potentiation/depression curve by applying a schottky tunneling region, which is generated in a schottky junction, to a synaptic operation, and a neuromorphic system using the same. Accordingly, the inventive concept may improve the integration and the performance of the neuromorphic system, because of producing higher learning efficiency without an additional circuit for improving the linearity and the symmetricity of the synapse.

The technical problems to be solved by the inventive concept are not limited to the aforementioned problems, and any other technical problems not mentioned herein will be clearly understood from the following description by those skilled in the art to which the inventive concept pertains.

According to an exemplary embodiment of the inventive concept, a neuromorphic synaptic device based on a charge trap and having linearity and symmetricity improved using a schottky junction includes a body layer formed on a semiconductor substrate; a source and a drain formed at a left side and a right side, or an upper side and a lower side of the body layer, a contact metal to form a schottky junction by making contact with the source and the drain, a gate insulating layer formed on the body layer and including an oxide layer and a charge storage layer, and a gate formed on the gate insulating layer.

The semiconductor substrate and the body layer may include any one of silicon (Si), silicon germanium (SiGe), strained Si, silicon carbide (SiC), and a group III-V compound semiconductor.

The semiconductor substrate may include a barrier material layer including one of a buried oxide, a buried n-well when the body layer is in a p type, a buried p-well when the body layer is in an n type, buried SiC, and buried SiGe.

The semiconductor substrate may function as a back gate to apply a voltage bias.

The body layer may be formed in any one of structures of a planar-type body layer, a trench-type body layer, a fin-type body layer, a nanowire-type body layer, or nanosheet-type body layer.

The source and the drain may have a horizontal structure in which a channel is formed in a horizontal direction to the semiconductor substrate, as the source and the drain are formed at the left side and the right side of the body layer, and a vertical pillar structure in which the channel is formed in a direction perpendicular to the semiconductor substrate, as the source and the drain are formed at the upper side and the lower side of the body layer.

The source and the drain may include any one of n-type silicon, p-type silicon, and metal silicide.

The source and the drain including the n-type silicon or the p-type silicon may be formed through at least one of a diffusion process, a solid-phase diffusion process, an epitaxial growth process, a selective epitaxial growth process, an ion implantation process, and the subsequent heat treatment process.

The source and the drain including the n-type silicon or the p-type silicon may be formed to have a specific doping concentration or less to form the schottky junction with the contact metal.

The source and drain including the metal silicide may include any one of tungsten (W), titanium (Ti), cobalt (Co), nickel (Ni), erbium (Er), ytterbium (Yb), samarium (Sm), yttrium (Y), gadollium (Gd), turbul (Tb), cerium (Ce), platinum (Pt), iridium (Ir), and any combination thereof.

The source and drain may form an asymmetric structure in a concentration gradient to block a sneaky path of a neuron and a synapse array.

The contact metal may include any one of aluminum (Al), molybdenum (Mo), chromium (Cr), palladium (Pd), platinum (Pt), nickel (Ni), titanium (Ti), gold (Au), tantalum (Ta), tungsten (W), silver (Ag), titanium nitride (TiN), tantalum nitride (TaN), and any combination thereof.

The gate insulating layer may include two oxide layers formed at opposite sides of the charge storage layer, or may include the charge storage layer and one oxide layer.

The charge storage layer may include any one of poly-silicon, amorphous silicon, a metal oxide, a silicon nitride, a silicon nano-crystal material, a metal oxide nano-crystal material, and any combination thereof.

In addition, the charge storage layer including the silicon nitride may include any one of a silicon nitride having a single characteristic and a material including at least two silicon nitrides having mutually different characteristics, as the composition ratio of Si and N is changed. The characteristic of the synaptic device may be adjusted and optimized, as the characteristic of the material is adjusted through various combinations changed depending on the positions of the at least two silicon nitrides having mutually different characteristics.

The oxide layer may include any one of a silicon oxide, a silicon oxynitride, an aluminum oxide, a hafnium oxide, a hafnium oxynitride, a zinc oxide, a zirconium oxide, a hafnium zirconium oxide (HZO), and the combination thereof.

The gate may include any one of, n-type polysilicon, p-type polysilicon, aluminum (Al), molybdenum (Mo), chromium (Cr), palladium (Pd), platinum (Pt), nickel (Ni), titanium (Ti), gold (Au), tantalum (Ta), tungsten (W), silver (Ag), titanium nitride (TiN), tantalum nitride (TaN), and any combination thereof.

The gate may have any one of a structure to surround the body layer in the form of a fin, a gate-all-around structure to surround the entire portion of the body layer, and a multiple-gate structure.

The neuromorphic synaptic device shows the synaptic weight and the conductance varied depending on an amount of charges stored in the charge storage layer, and potentiates or depresses the synaptic weight and the conductance by changing the amount of charges stored in the charge storage layer by applying a voltage signal to the gate.

According to an embodiment of the inventive concept, the neuromorphic system includes a neuromorphic synaptic device based on a charge trap and having linearity and symmetricity improved by using a schottky junction, and the synaptic device forms a schottky junction, as the source and the drain make contact with the contact metal.

According to another exemplary embodiment of the inventive concept, a neuromorphic synaptic device based on a charge trap and having linearity and symmetricity improved using a schottky junction includes a body layer formed on a semiconductor substrate, a source and a drain formed at a left side and a right side, or an upper side and a lower side of the body layer, a contact metal to form a schottky junction by making contact with the source and the drain, a gate insulating layer formed on the body layer and including an oxide layer and a charge storage layer, and a gate formed on the gate insulating layer. The source and the drain have an asymmetric structure in concentration gradient to block a sneaky path of a neuron and a synapse array.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIGS. 1A to 1D illustrate the structures of neuromorphic synaptic devices based on a charge trap and having improved linearity and improved symmetricity, according to an embodiment of the inventive concept;

FIGS. 2A and 2B illustrate an energy band diagram and an electrical characteristic to explain the operating principle of a neuromorphic synaptic device based on a charge trap and having improved linearity and improved symmetricity, according to an embodiment of the inventive concept;

FIGS. 3A and 3B illustrate a scanning electron microscope (SEM) and a transmission electron microscope image (TEM) of a neuromorphic synaptic device having a horizontal structure actually fabricated, based on a charge trap, and having improved linearity and improved symmetricity, according to an embodiment of the inventive concept;

FIGS. 4A and 4B illustrate graphs of electrical measurement results of a neuromorphic synaptic device having a horizontal structure actually fabricated, based on a charge trap, and having improved linearity and improved symmetricity, according to an embodiment of the inventive concept;

FIG. 5 illustrates a result graph of a simulation (MNIST) for recognizing a handwriting using a neuromorphic synaptic device having a horizontal structure actually fabricated, based on a charge trap, and having improved linearity and improved symmetricity, according to an embodiment of the inventive concept;

FIGS. 6A and 6B illustrate a scanning electron microscope (SEM) and a transmission electron microscope image (TEM) of a neuromorphic synaptic device having a vertical pillar structure actually fabricated, based on a charge trap, and having improved linearity and improved symmetricity, according to an embodiment of the inventive concept; and

FIGS. 7A and 7B illustrate graphs of electrical measurement results of a neuromorphic synaptic device having a vertical pillar structure actually fabricated, based on a charge trap, and having improved linearity and improved symmetricity, according to an embodiment of the inventive concept.

### DETAILED DESCRIPTION

Advantage points and features of the inventive concept and a method of accomplishing thereof will become apparent from the following description with reference to the following figures, wherein embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. The inventive concept may be defined by scope of the claims. Meanwhile, the terminology used herein to describe embodiments of the inventive concept is not intended to limit the scope of the inventive concept.

The terminology used herein is provided for explaining embodiments, but the inventive concept is not limited thereto. As used herein, the singular terms “a,” “an” and “the” are intended to include the plural forms as well, unless the context clearly indicates otherwise. Furthermore, it will be further understood that the terms “comprises”, “comprising,” “includes” and/or “including”, when used herein, specify the presence of stated components, steps, operations, and/or devices, but do not preclude the presence or addition of one or more other components, steps, operations and/or devices.

Unless otherwise defined, all terms (including technical and scientific terms) used herein have the same meaning as commonly understood by those skilled in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the inventive concept will be described in more detail with reference to accompanying drawings. The same reference numerals are used with respect to the same elements on drawings, and the redundant details of the same elements will be omitted.

According to embodiments of the inventive concept, the subject matter is to improve the linearity and the symmetricity of a potentiation/depression curve by applying a schottky tunneling region, which is generated in a schottky junction, to a synpatic operation.

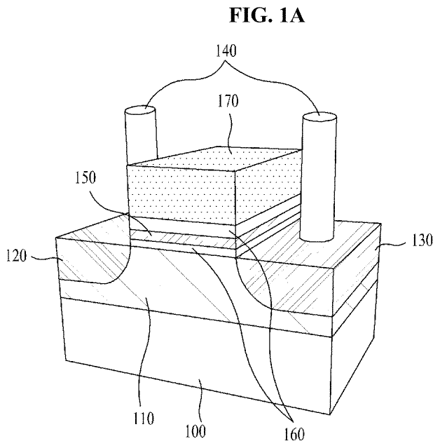

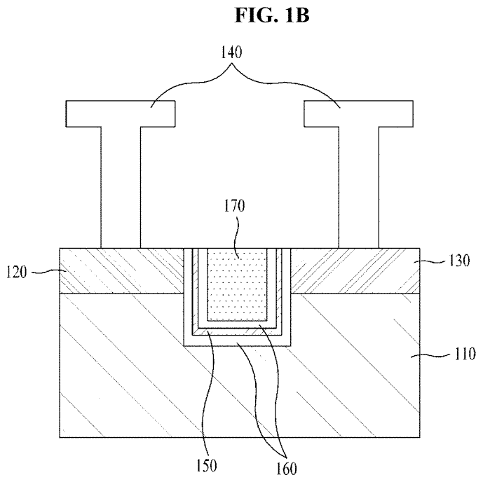

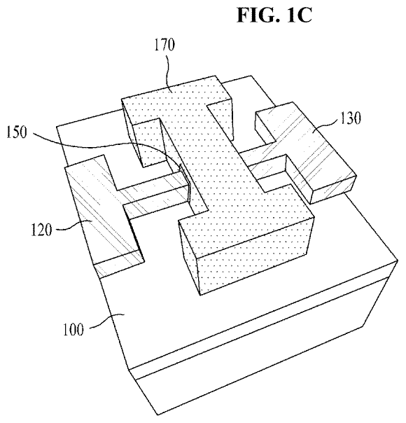

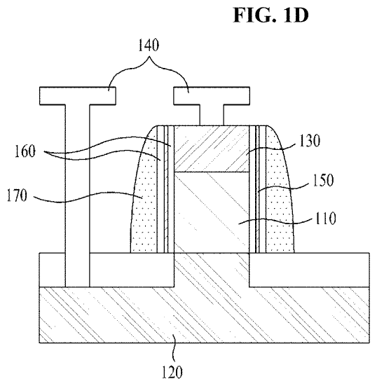

FIGS. 1A to 1D illustrate the structures of a neuromorphic synaptic device, based on a charge trap, and having improved linearity and improved symmetricity, according to an embodiment of the inventive concept. FIG. 1A illustrates the structure of a neuromorphic synaptic device having a planar-type body layer, FIG. 1B illustrates the structure of a neuromorphic synaptic device of a trench-type body layer, FIG. 1C illustrates the structure of a neuromorphic synaptic device of a fin-type body layer, and FIG. 1D illustrates a neuromorphic synaptic device having a vertical pillar-type body layer.

Referring to FIGS. 1A to 1D, a neuromorphic synaptic device based on a charge trap and having improved linearity and improved symmetricity includes a substrate 100, a body layer 110, a source 120, a drain 130, a contact metal 140, a charge storage layer 150, oxide layers 160, and a gate 170.

Hereinafter, a neuromorphic synaptic device (transistor) based on a charge trap and having improved linearity and improved symmetricity will be described while focusing on an N-type channel device, according to an embodiment of the inventive concept.

Referring to FIGS. 1A to 1D, the body layer 110 is positioned on the substrate 100, for example, a semiconductor substrate. In other words, the body layer 110 is formed on the semiconductor substrate 100.

The substrate 100 and the body layer 110 may include any one of silicon (Si), silicon germanium (SiGe), strained Si, silicon carbide (SiC), a group III-V compound semiconductor, or other semiconductor materials.

The substrate 100 may include a barrier material layer including one of a buried oxide, a buried n-well when the body layer is in a p-type, a buried p-well when the body layer is in an n type, buried SiC, and buried SiGe.

The substrate 100 may function as a back gate to apply a voltage bias.

The body layer 110 may be formed in any one of structures of a planar-type body layer, a trench-type body layer, a fin-type body layer, a nanowire-type body layer, or a nanosheet-type body layer, as illustrated in FIGS. 1A to 1D.

The source 120 and the drain 130 are formed at opposite sides of the body layer 110.

The source 120 and the drain 130 may include any one of n-type silicon, p-type silicon, and metal silicide. In this case, the source 120 and the drain 130 may have a type different from that of the body layer 110. For example, when the source 120 and the drain 130 are in a p-type, the body layer 110 may be in an n-type. When the source 120 and the drain 130 are in an n-type, the body layer 110 may be in a p-type.

The source 120 and the drain 130 including the n-type silicon or the p-type silicon may be formed through at least one of a diffusion process, a solid-phase diffusion process, an epitaxial growth process, a selective epitaxial growth process, an ion implantation process, and the subsequent heat treatment process.

The source 120 and the drain 130 including the n-type silicon or the p-type silicon may be formed to have a light doping concentration, for example, a preset specific doping concentration or less, to form a schottky junction with the contact metal 140.

The source 120 and the drain 130 including the n-type silicon or p-type silicon show asymmetric structures having mutually different doping concentrations.

The structures may be used to block the sneaky path of a neuron and a synapse array without an additional selector.

The source 120 and drain 130 including the metal silicide include a metal silicide including any one of tungsten (W), titanium (Ti), cobalt (Co), nickel (Ni), erbium (Er), ytterbium (Yb), samarium (Sm), yttrium (Y), gadollium (Gd), turbul (Tb), cerium (Ce), platinum (Pt), iridium (Ir), and any combination thereof, or any one of other metal material. In this case, the corresponding transistor may be a schottky barrier transistor.

Contact metals 140, which are formed on the source 120 and the drain 130, may include any one of aluminum (Al), molybdenum (Mo), chromium (Cr), palladium (Pd), platinum (Pt), nickel (Ni), titanium (Ti), gold (Au), tantalum (Ta), tungsten (W), silver (Ag), titanium nitride (TiN), tantalum nitride (TaN), and any combination thereof, or any one of other metal materials.

The gate insulating layers 150 and 160 are formed on the body layer 110, and include the charge storage layer 150 and two oxide layers 160 positioned at opposite sides of the charge storage layer 150.

The oxide layer 160 formed on the body layer 110 insulates the body layer 110 from the charge storage layer 150. The oxide layer 160, which is named a tunneling oxide, may include any one of a silicon oxide, an aluminum oxide, a hafnium oxide, a hafnium oxynitride, a zinc oxide, a zirconium oxide, a hafnium zirconium oxide (HZO), and any combination thereof, or any one of other oxide layers.

The charge storage layer 150 is present on the oxide layer 160, and allows mutually different weights depending on an amount of charges stored in the charge storage layer 150 to perform a synapse operation. The charge storage layer 150 may include any one of poly-silicon, amorphous silicon, a metal oxide, a silicon nitride, a silicon nano-crystal material, a metal oxide nano-crystal material, and any combination thereof, or other charge storage layers.

The charge storage layer 150 including a silicon nitride may adjust the characteristic of the synaptic device by adjusting the composition ratio between Si and N. For example, when the proportion of Si is increased, potentiation efficiency is increased. When the proportion of N is increased, a retention characteristic is improved. In addition, when a region, which is closer to the body layer 110, of the charge storage layer 150 has the higher proportion of Si, and a region, which is away from the body layer 110, of the charge storage layer 150 has the higher proportion of N, thereby forming a double layer. In this case, both of the potentiation characteristic and the retention characteristic may be excellently performed. In other words, the storage charge layer 150 including the silicon nitride may include a silicon nitride having a single characteristic and at least two silicon nitrides having mutually different characteristics, as the composition ratio between Si and N is varied. Accordingly, the at least two silicon nitrides having the mutually different characteristics are adjusted to be various combinations depending on positions. Accordingly, the characteristic of the synaptic device may be adjusted and optimized.

One oxide layer 160 formed on the charge storage layer 150 insulates the charge storage layer 150 from the gate 170 and is named a blocking oxide layer. Even the oxide layer 160 may include any one of a silicon oxide, an aluminum oxide, a hafnium oxide, a hafnium oxynitride, a zinc oxide, a zirconium oxide, a hafnium zirconium oxide (HZO), and any combination thereof, or any one of other oxide layers.

The gate 170 may be formed on the gate insulating layers 150 and 160 may include any one of n-type polysilicon, p-type polysilicon, and metal. The relevant metal may include any one of aluminum (Al), molybdenum (Mo), chromium (Cr), palladium (Pd), platinum (Pt), nickel (Ni), titanium (Ti), gold (Au), tantalum (Ta), tungsten (W), silver (Ag), a titanium nitride (TiN), a tantalum nitride (TaN), and any combination thereof, or any one of other metal materials.

The gate 170 may have the structure to surround the body layer 110 in the form of a fin.

The gate 170 may have a gate-all-around structure to surround the entire portion of the body layer 110.

The gate 170 may have a multiple-gate structure.

The neuromorphic synaptic device may potentiate or depress a synaptic weight and a conductance by applying a voltage signal to the gate 170 to change an amount of charges stored in the charge storage layer 150, depending on occasions.

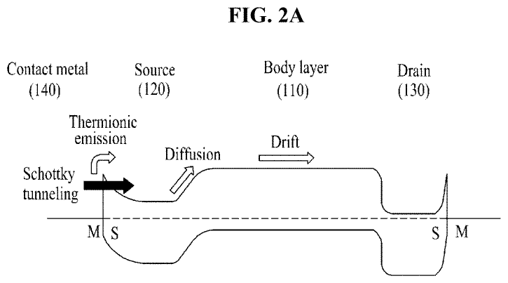

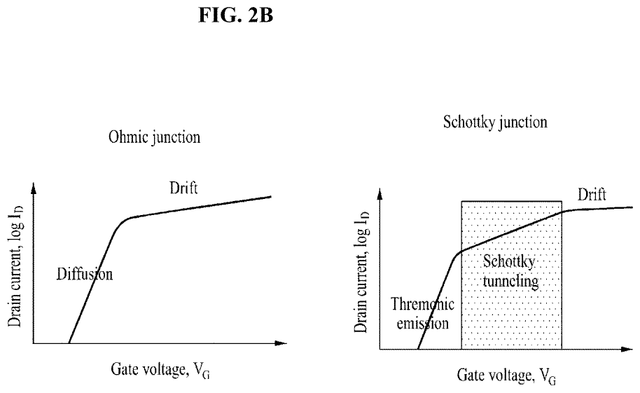

FIGS. 2A and 2B illustrate an energy band diagram and an electrical characteristic to explain the operating principle of a neuromorphic synaptic device based on a charge trap and having improved linearity and symmetricity, according to an embodiment of the inventive concept.

Referring to FIG. 2A, when the source 120 has a lower doping concentration, the source 120 and the contact metal 140 form a non-ohmic schottky junction. In this case, a schottky tunneling current is generated to flow through a tunneling barrier. Referring to a current graph illustrating a drain current as a function of a gate voltage in FIG. 2B, a typical transistor having an ohmic junction with the contact metal 140 formed due to the heavier doping concentration of the source 120 has two dominant currents of a diffusion current in a sub-threshold region and a drift current in a strong inversion region. However, in the schottky junction formed due to the lighter doping concentration of the source 120, a thermionic current dominantly flows in a sub-threshold region, a schottky tunneling current dominantly flows in a transition region, and a drift current dominantly flows in an inversion region. In the case of the schottky tunneling current in the transition region, the drain current is exponentially increased with respect to the gate voltage. Accordingly, when the relevant region is employed, the synaptic device having higher linearity and the higher symmetricity may be realized. In more detail, the original cause of degrading the linearity and the symmetricity of the charge trap flash memory is because the conductance, which is varied depending on a Fowler-Nordheim tunneling operation serving as a principle of injecting or removing charges, shows the form of a log function depending on the number of times of input signals. However, the conductance in the schottky tunneling region shows the form of an exponential function depending on the gate voltage, and thus is canceled with the conductance depending on the FN tunneling operation. Accordingly, the improved linearity and the improved symmetricity may be represented.

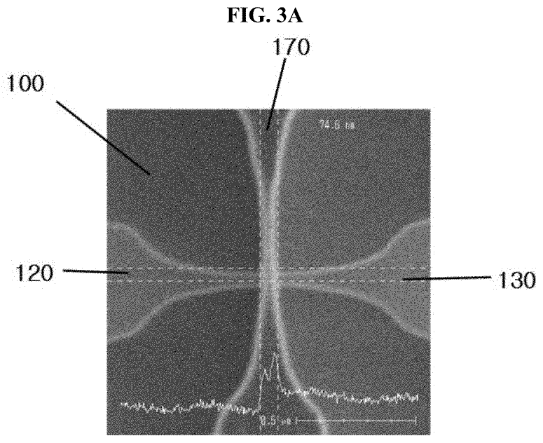

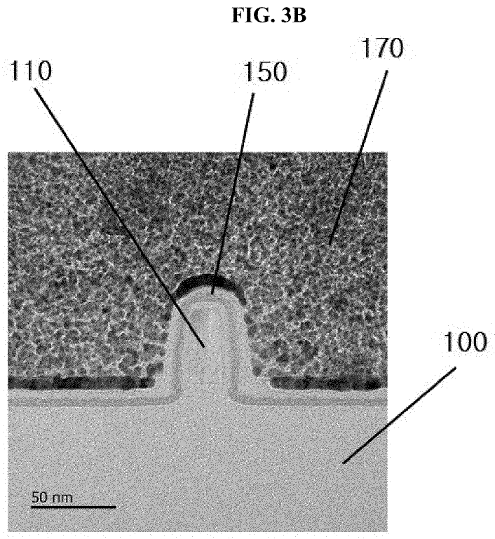

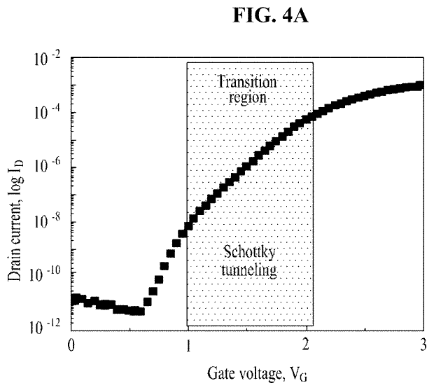

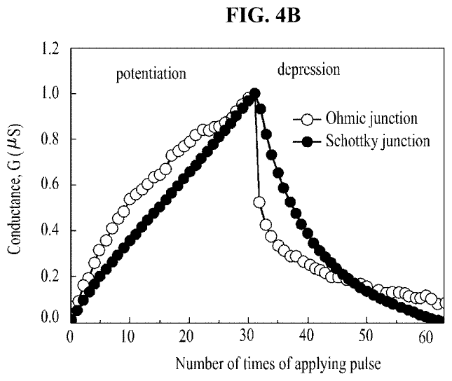

FIGS. 3A and 3B illustrate a scanning electron microscope (SEM) and a transmission electron microscope image (TEM) of a neuromorphic synaptic device having a horizontal structure actually fabricated, based on a charge trap, and having improved linearity and improved symmetricity, according to an embodiment of the inventive concept, and FIGS. 4A and 4B illustrate graphs of electrical measurement results of a neuromorphic synaptic device having a horizontal structure actually fabricated, based on a charge trap, and having improved linearity and improved symmetricity, according to an embodiment of the inventive concept

In this case, the neuromorphic synaptic device having the horizontal structure, based on a charge trap, and having the improved linearity and improved symmetricity are fabricated on a bulk-type silicon substrate. To form the schottky junction for the source 120 and the drain 130, phosphorus (P) ions are implanted in a dose of 5×10¹³ cm⁻² with the energy of 10 keV. In this case, the horizontal structure refers to a structure in which a channel is formed in a horizontal direction with respect to the substrate, as the source 120 and the drain 130 are formed at left and right sides of the body layer 110.

FIG. 4A is a graph illustrating the measurement result of a drain current as a function of a gate voltage. It may be recognized from the measurement result that a transition region having a dominant schottky tunneling current is present.

As illustrated in FIG. 4B, a potentiation/depression characteristic is recognized by using a reading voltage corresponding to the transition region. In addition, FIG. 4B shows the characteristic of the typical synapse device that the conductance of the synaptic device is changed in response to the potentiation and depression signals. In addition, it may be recognized from FIG. 4B that more excellent linearity and symmetricity are shown, as compared to the synaptic device having the ohmic junction instead of the schottky junction.

For the measurement of FIG. 4B, a potentiation pulse having an amplitude of −9 V and the time of 0.1 ms and the depression pulse having an amplitude of 10 V and the time of 30 μs are used. In addition, a gate voltage of 1.5 V and a drain voltage of 1 V may be used for the reading voltage to extract the conductance.

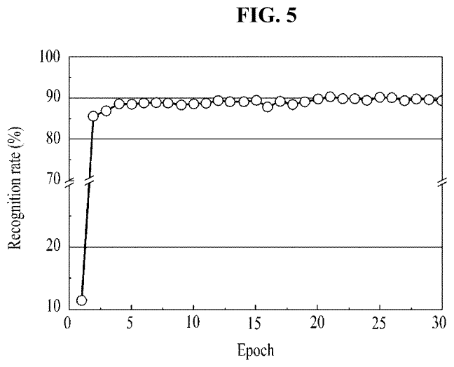

FIG. 5 illustrates a result graph of a simulation (MNIST) for recognizing a handwriting using a neuromorphic synaptic device having a horizontal structure actually fabricated, based on a charge trap, and having improved linearity and improved symmetricity, according to an embodiment of the inventive concept. The significant high recognition rate of 90% may be recognized from FIG. 5. For the MNIST simulation, a deep neural network (DNN) including two hidden layers may be employed.

Meanwhile, the synaptic device having the horizontal structure, in which the source, the body layer, and the drain are formed in a horizontal direction, has at least the integration of 6 F². However, the integration of the synaptic device needs to be improved to the maximum, based on that the human brain has about 10¹⁵ synapses. Accordingly, as the synaptic device is formed the vertical pillar structure, in which the source, the body layer, and the drain are provided in a vertical direction, the integration of the synaptic device may be improved to at least 4 F².

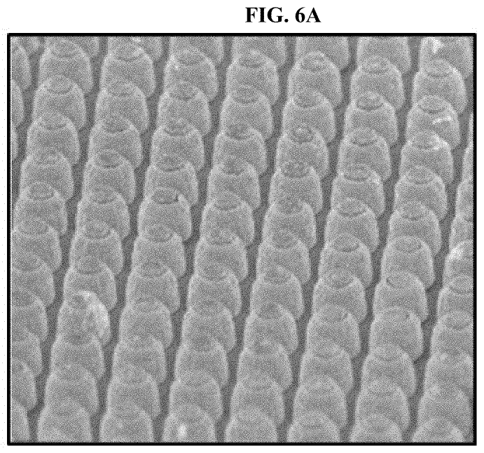

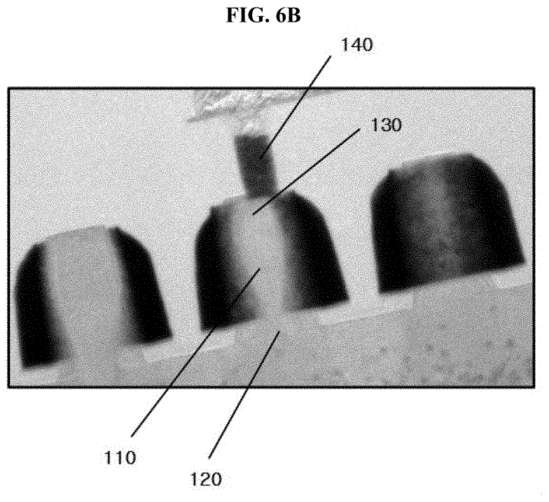

FIGS. 6A and 6B illustrate a scanning electron microscope (SEM) and a transmission electron microscope image (TEM) of a neuromorphic synaptic device having a vertical pillar structure actually fabricated, based on a charge trap, and having improved linearity and improved symmetricity, according to an embodiment of the inventive concept. It may be recognized from FIGS. 6A and 6B that the source 120, the body layer 110, and the drain 130 are vertically formed, and that numerous synapse devices are formed in a narrower region.

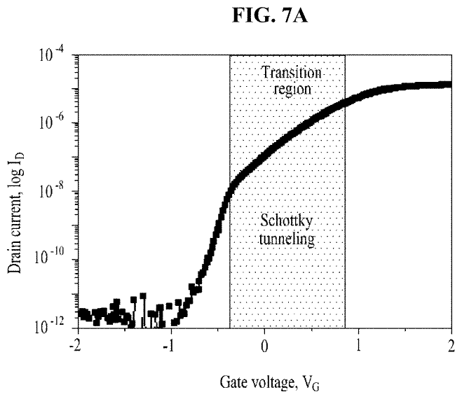

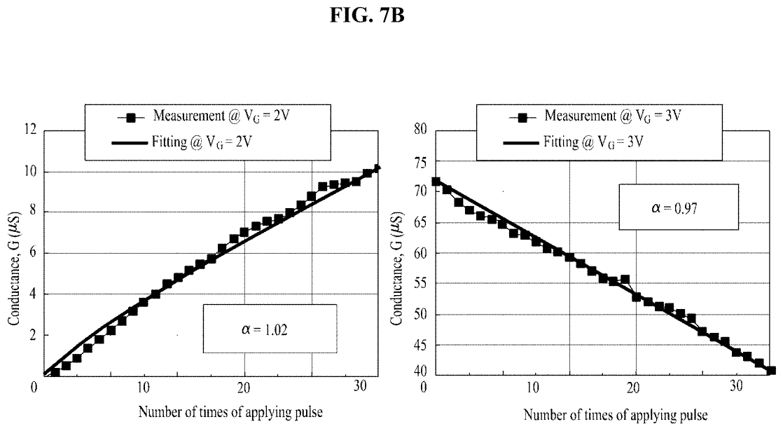

FIGS. 7A and 7B illustrate graphs of electrical measurement results of a neuromorphic synaptic device having a vertical pillar structure actually fabricated, based on a charge trap, and having improved linearity and improved symmetricity, according to an embodiment of the inventive concept.

FIG. 7A illustrate a graph of a measurement result of a drain current as a function of a gate voltage. It may be recognized from FIG. 7A that the transition region having the dominant schottky tunneling current is present, which is similar to the synaptic device having the horizontal structure.

FIG. 7B illustrates the potentiation/depression characteristic using the reading voltage corresponding to the transition region. FIG. 7B shows the typical characteristic of the synaptic device that the conductance of the synaptic device is varied in response to the potentiation and depression signal, similarly to the synaptic device having the horizontal structure, which indicates the linearity close to an ideal value (α=1).

As described above, according to the technology of the embodiment of the inventive concept, when the charge trap flash memory having the schottky junction is used, the neuromorphic synaptic device having improved linearity and symmetricity and the potentiation/depression curve may be implemented. Accordingly, higher learning efficiency may be produced without the additional circuit for improving the linearity and the symmetricity of the synapse. Accordingly, the integration and the performance of the neuromorphic system may be considerably improved.

In detail, according to the technology of the embodiment of the inventive concept, when the source and drain regions are intentionally and lightly doped, the non-ohmic schottky junction is formed with the contact metal. Accordingly, the region through which the current flows is present due to the schottky tunneling.

Therefore, the conductance in the schottky tunneling region has an exponential function depending on the gate voltage, and thus is canceled with the log function resulting from the FN tunneling operation, thereby producing the improved linearity and the improved symmetricity.

In addition, according to the inventive concept, the neuromorphic system may be implemented by using the neuromorphic synaptic device based on the charge trap and having the linearity and symmetricity improved by using the schottky junction. The neuromorphic system may include a neuromorphic chip using the neuromorphic synaptic device based on the charge trap and having the linearity and symmetricity improved by using the schottky junction

In other words, when the neuromorphic system may be implemented by using the neuromorphic synaptic device based on the charge trap and having the improved linearity and improved symmetricity, higher learning efficiency may be produced without an additional circuit for improving the linearity and the symmetricity of the synapse. Accordingly, the integration and the performance of the neuromorphic system may be considerably improved.

In this case, the neuromorphic chip may include any one of a resistive switching memory device (RRAM), a memristor, a charge trap memory device (flash memory), a phase change memory device (PCM), or a ferroelectric RAM (FeRAM).

In this case, the neuromorphic chip may include at least one additional component of a resistor, a capacitor, another transistor, and another inverter in a limited region.

According to an embodiment of the inventive concept, when the charge trap flash memory device having the schottky junction is used, the neuromorphic synaptic device having the potentiation/depression curve of the improved linearity and the improved symmetricity may be implemented. Accordingly, the inventive concept may improve the integration and the performance of the neuromorphic system, because of producing higher learning efficiency without an additional circuit for improving the linearity and the symmetricity of the synapse.

In more detail, the original cause of degrading the linearity and the symmetricity of the charge trap flash memory is because the conductance, which is varied depending on a Fowler-Nordheim tunneling operation serving as a principle of injecting or removing charges, shows the form of a log function depending on the number of times of input signals. In this case, when the source and drain regions are intentionally and lightly doped, the non-ohmic schottky junction with the contact metal is formed. Accordingly, a region, through which a current flows, is formed through the schottky tunneling. In this case, the conductance in the schottky tunneling region has an exponential function depending on the gate voltage, and thus is canceled with the log function resulting from the FN tunneling operation. Accordingly, the improved linearity and the improved symmetricity may be produced.

The effects of the inventive concept are not limited to the aforementioned problems, and may be variously expanded without departing from the technical spirit and the technical scope of the inventive concept.

Hereinabove, although the inventive concept has been described with reference to embodiments and the accompanying drawings, the inventive concept is not limited thereto, but may be variously modified and altered by those skilled in the art to which the inventive concept pertains without departing from the spirit and scope of the disclosure claimed in the following claims. For example, although the technologies are performed in a sequence different from the above-described sequence, and/or components of the above-described system, structure, device, or circuit are coupled or assembled in the form different from the above-described form, substituted or replaced with another component or another equivalent, a proper result can be accomplished.

Therefore, other embodiments, and equivalents fall into the scope of attached claims.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. A neuromorphic synaptic device based on a charge trap and having linearity and symmetricity improved by using a schottky junction, the neuromorphic synaptic device comprising:
a body layer formed on a semiconductor substrate;
a source and a drain formed at a left side and a right side, or an upper side and a lower side of the body layer;
a contact metal configured to form a schottky junction by making contact with the source and the drain;
a gate insulating layer formed on the body layer, and including an oxide layer and a charge storage layer; and
a gate formed on the gate insulating layer.

2. The neuromorphic synaptic device of claim 1, wherein the semiconductor substrate and the body layer include:
one of silicon (Si), silicon germanium (SiGe), strained Si, silicon carbide (SiC), and a group III-V compound semiconductor.

3. The neuromorphic synaptic device of claim 1, wherein the semiconductor substrate includes:
a barrier material layer including one of a buried oxide, a buried n-well when the body layer is in a p type, a buried p-well when the body layer is in an n type, buried SiC, and buried SiGe.

4. The neuromorphic synaptic device of claim 1, wherein the semiconductor substrate functions as a back gate to apply a voltage bias.

5. The neuromorphic synaptic device of claim 1, wherein the body layer is formed in one of structures of a planar-type body layer, a trench-type body layer, a fin-type body layer, a nanowire-type body layer, or nanosheet-type body layer.

6. The neuromorphic synaptic device of claim 1, wherein the source and the drain have one of a horizontal structure in which a channel is formed in a horizontal direction to the semiconductor substrate, as the source and the drain are formed at the left side and the right side of the body layer, and a vertical pillar structure in which the channel is formed in a direction perpendicular to the semiconductor substrate, as the source and the drain are formed at the upper side and the lower side of the body layer.

7. The neuromorphic synaptic device of claim 1, wherein the source and the drain include:
one of n-type silicon, p-type silicon, and metal silicide.

8. The neuromorphic synaptic device of claim 7, wherein the source and the drain including the n-type silicon or the p-type silicon are formed through at least one of a diffusion process, a solid-phase diffusion process, an epitaxial growth process, a selective epitaxial growth process, an ion implantation process, and the subsequent heat treatment process.

9. The neuromorphic synaptic device of claim 7, wherein the source and the drain including the n-type silicon or the p-type silicon are formed to have a specific doping concentration or less to form the schottky junction with the contact metal.

10. The neuromorphic synaptic device of claim 7, wherein the source and drain including the metal silicide includes:
one of tungsten (W), titanium (Ti), cobalt (Co), nickel (Ni), erbium (Er), ytterbium (Yb), samarium (Sm), yttrium (Y), gadollium (Gd), turbul (Tb), cerium (Ce), platinum (Pt), iridium (Ir), and any combination thereof.

11. The neuromorphic synaptic device of claim 1, wherein the source and drain form an asymmetric structure in a concentration gradient to block a sneaky path of a neuron and a synapse array.

12. The neuromorphic synaptic device of claim 1, wherein the contact metal include:
one of aluminum (Al), molybdenum (Mo), chromium (Cr), palladium (Pd), platinum (Pt), nickel (Ni), titanium (Ti), gold (Au), tantalum (Ta), tungsten (W), silver (Ag), titanium nitride (TiN), tantalum nitride (TaN), and a combination thereof.

13. The neuromorphic synaptic device of claim 1, wherein the gate insulating layer includes:
two oxide layers formed at opposite sides of the charge storage layer; or
the charge storage layer and one oxide layer.

14. The neuromorphic synaptic device of claim 13, wherein the charge storage layer includes:
one of poly-silicon, amorphous silicon, a metal oxide, a silicon nitride, a silicon nano-crystal material, a metal oxide nano-crystal material, and a combination thereof.

15. The neuromorphic synaptic device of claim 14, wherein the charge storage layer including the silicon nitride includes:
one of a silicon nitride having a single characteristic and a material including at least two silicon nitrides having mutually different characteristics, as a composition ratio of silicon (Si) and nitrogen (N) is changed, and
wherein a characteristic of the neuromorphic synaptic device is adjusted and optimized, as a characteristic of the material is adjusted through various combinations changed depending on positions of the at least two silicon nitrides having the mutually different characteristics.

16. The neuromorphic synaptic device of claim 1, wherein the oxide layer include:
one of a silicon oxide, silicon oxynitride, an aluminum oxide, a hafnium oxide, a hafnium oxynitride, a zinc oxide, a zirconium oxide, a hafnium zirconium oxide (HZO), and a combination thereof.

17. The neuromorphic synaptic device of claim 1, wherein the gate includes:
one of n-type polysilicon, p-type polysilicon, aluminum (Al), molybdenum (Mo), chromium (Cr), palladium (Pd), platinum (Pt), nickel (Ni), titanium (Ti), gold (Au), tantalum (Ta), tungsten (W), silver (Ag), titanium nitride (TiN), tantalum nitride (TaN), and a combination thereof.

18. The neuromorphic synaptic device of claim 1, wherein the gate has one of a structure to surround the body layer in a form of a fin, a gate-all-around structure to surround an entire portion of the body layer, and a multiple-gate structure.

19. The neuromorphic synaptic device of claim 1, wherein the neuromorphic synaptic device shows a synpatic weight and a conductance through an amount of charges stored in the charge storage layer, and potentiates or depress the synpatic weight and the conductance by changing the amount of charges stored in the charge storage layer by applying a voltage signal to the gate.

20. A neuromorphic system comprising:
a neuromorphic synaptic device based on a charge trap and having linearity and symmetricity improved by using a schottky junction,
wherein the synaptic device forms a schottky junction, as a source and a drain make contact with contact metal.

21. A neuromorphic synaptic device based on a charge trap and having linearity and symmetricity improved by using a schottky junction, the neuromorphic synaptic device comprising:
a body layer formed on a semiconductor substrate;
a source and a drain formed at a left side and a right side or an upper side and a lower side of the body layer;
a contact metal configured to form a schottky junction by making contact with the source and the drain;
a gate insulating layer formed on the body layer and including an oxide layer and a charge storage layer; and
a gate formed on the gate insulating layer,
wherein the source and the drain have an asymmetric structure in concentration gradient to block a sneaky path of a neuron and a synapse array.
